(19) United States
(12) Patent Application Publication
(10) Pub. No.: US 2026/0206558 A1
(43) Pub. Date: Jul. 16, 2026

(54) SEMICONDUCTOR DEVICE INTERCONNECT LAYER FORMATION BY SELECTIVE ION IMPLANTATION

(71) Applicant: Axcelis Technologies, Inc., Beverly, MA (US)

(72) Inventor: Anthony Lee, Malden, MA (US)

(73) Assignee: Axcelis Technologies, Inc., Beverly, MA (US)

(21) Appl. No.: 19/024,583

(22) Filed: Jan. 16, 2025

(51) Int. Cl. H01L 21/768; H01J 37/317; H01L 21/3215

(52) U.S. Cl. CPC H10W 20/064; H01J 37/3171; H10P 32/30; H10W 20/063

(57) ABSTRACT

A method for forming an interconnect layer for a semiconductor device includes depositing a first conductive layer on a semiconductor wafer, the first conductive layer having a thickness less than a desired final thickness of the interconnect layer; implanting an implant species into a top surface of the first conductive layer, wherein the implant species is selected so as to mitigate a stress developed in the first layer; and depositing one or more additional conductive layers upon the implanted first conductive layer up to the desired final thickness of the interconnect layer.

### BACKGROUND

The present invention relates generally to semiconductor device manufacturing and, more specifically, to a method of improving characteristic properties of conductive interconnect structures formed on semiconductor devices through selective ion implantation.

In the manufacture of semiconductor devices and other related products, ion implantation systems are used to impart dopant elements into semiconductor wafers, display panels, or other types of workpieces. Typical ion implantation systems or ion implanters impact a workpiece with an ion beam utilizing a known recipe or process in order to produce n-type or p-type doped regions, or to modify layers in the workpiece to enhance or impart other beneficial properties, such as hydrogen ions to produce cleave planes. When used for doping semiconductors, the ion implantation system injects selected ion species to produce the desired extrinsic material.

Typically, dopant atoms or molecules are ionized and isolated, formed into a beam, accelerated or decelerated to a desired final implant energy, and implanted into a workpiece. The dopant ions physically bombard and enter the surface of the workpiece, and subsequently come to rest below the workpiece surface in the crystalline lattice structure thereof at a depth determined by the incident implant energy and the ion mass.

In recent years, the use of ion implantation has extended to materials modification of the implanted surface, using novel implanted species, in order to change other properties of the substrate beyond the sheet resistance. These additional uses have included, for example, etch rate modification, electron/hole mobility enhancement and similar desirable effects in semiconductor manufacturing. Implanted species in this context have included, for example, carbon, germanium and similar non-electrical dopants.

### SUMMARY

In one embodiment, a method for forming an interconnect layer for a semiconductor device includes depositing a first conductive layer on a semiconductor wafer, the first conductive layer having a thickness less than a desired final thickness of the interconnect layer; implanting an implant species into a top surface of the first conductive layer, wherein the implant species is selected so as to mitigate a stress developed in the first layer; and depositing one or more additional conductive layers upon the implanted first conductive layer up to the desired final thickness of the interconnect layer.

In another embodiment, a combination ion implantation and deposition system includes a process chamber, an ion source configured to generate a desired ion species for implantation, and a beamline module configured to transport the desired ion species to the process chamber, wherein the process chamber further includes a secondary chamber having a material deposition source therein. A controller is configured to deposit, using the material deposition source, a first conductive layer on a semiconductor wafer disposed within the process chamber, the first conductive layer having a thickness less than a desired final thickness of an interconnect layer of a semiconductor device formed on the semiconductor wafer, implant the desired implant species into a top surface of the first conductive layer, wherein the implant species is selected so as to mitigate a stress developed in the first layer, and deposit, using the material deposition source, one or more additional conductive layers upon the implanted first conductive layer up to the desired final thickness of the interconnect layer.

### BRIEF DESCRIPTION OF THE DRAWINGS

Aspects of the present disclosure are best understood from the following detailed description when read with the accompanying figures.

FIG. 1(a) through FIG. 1(e) is a series of cross-sectional views illustrating a conventional process of forming metal lines for a semiconductor device.

FIG. 2(a) is an image of patterned metal lines formed by the process of FIG. 1(a)-1(e).

FIG. 2(b) is an enlarged view of the highlighted portion of the image in FIG. 2(a).

FIG. 3 is a flowchart diagram illustrating a method of forming an interconnect layer for a semiconductor device using selective ion implantation, in accordance with an embodiment of the invention.

FIG. 4(a) through FIG. 4(j) is a series of cross-sectional views further illustrating the exemplary method of FIG. 3.

FIG. 5 depicts a system level representation of an exemplary semiconductor manufacturing system comprising a combination ion implantation and deposition system suitable for implementing the method of the present embodiments.

### DETAILED DESCRIPTION

Advanced logic devices (e.g., 2 nm node and below) are facing challenges in interconnect scaling, particularly with sub 20 nm metal pitch, using conventional Damascene or Dual-Damascene Cu technology when applied to back end-of-line (BEOL) manufacturing of applications with narrow critical dimension (CD). Node size for non-planar devices is governed principally by their contacted poly pitch (CPP), minimum metal pitch (MMP) and track height. Ruthenium has been posited as an alternative material for interconnects, as it has many advantageous properties: it exhibits improved signal transfer; it offers lower contact resistance over conventional Cu-based processes, not requiring a diffusion barrier, and not requiring the same aggressive Cu-CMP process steps for surface topology control. Furthermore, ruthenium HCP (Hexagonal Close Packed) crystal structure has good lattice match with Cu FCC (Face Centered Cubic), and in general the metal oxide or halide etch by-products from Ru have substantially lower boiling points.

Attempts to integrate ruthenium interconnects into advanced logic process flows using bulk or monolithic deposition method can be a source of issues such as line break defectivity and line edge roughness (LER), as has been identified by the inventor. Solutions under investigation include additional process steps of adding TiN or W defect mitigation layers (DMLs), however these require modified/additional Direct Metal Etch sequences to be incorporated into the manufacturing flow, thereby reducing throughput. While line breaks may be reduced, LER and LWR issues remain. Increased bridging with DML, particularly at smaller node sizes, requires new/modified etch and clean steps. Further penalties from increased resistance (R_{c}) may remain at long line length. High resistivity, high-aspect feature shape deformation can occur by subsequent integration processes (anneal, clean, etc.). Even with optimized etch processes, single layer Ru deposition requires a main etch gas and also an additional passivation gas to mitigate resultant or inherent LER and LWR. Wet cleaning is also required for thick, abrupt profile Ru lines. As such, compromises on the final line thickness of the Ru interconnect are required, impacting resistivity.

While the creation of intermediate layers embedded in BEOL stacks are known, such as that shown in U.S. Pat. No. 9,570,558, these are for trap-rich layers in other process flows and are not related to interconnect deposition. Although ion implantation into metal surfaces to mitigate undesirable effects has been described (e.g., U.S. Patent Application Publication US2007/0184694A1), such techniques do not enable multiple metal deposition steps and consequently do not take advantage of interfacial grain growth and stress relaxation to improve the final product performance.

In view of the above, embodiments of the present invention are directed generally towards an improved method of forming conductive structures in back end of line (BEOL) processing through the combined use of multiple deposition steps with an intervening ion implantation to the deposited layers. More particularly, the methods of the present invention provide a novel way to implant these lines in partial deposition steps. The interconnect may, for example, be a noble metal such as Mo or Ru. In other examples, the interconnect may be formed from graphene, combinatorial metals, or other novel materials.

In the manufacture of advanced logic semiconductors, or other CMOS devices, ion implantation has been used to create transistor junctions, via doping of source, gate and drain regions with electrically active atoms such as phosphorus (P), arsenic (As) or boron (B). More recently, implantation of electrically inactive dopants such as carbon (C), (Si) or hydrogen (H) have been used to modify other material properties of the semiconductor substrates.

Noble metals, for example ruthenium, molybdenum and materials with similar properties including electrical conductivity, stability to reactive gases, and purity, are appropriate materials for use in semiconductor device manufacturing due to several inherent properties such as low bulk resistivity and corrosion resistance to existing semiconductor process chemistries. These have advantageous properties relative to the existing Cu-based dual Damascene processes. Materials such as graphene and combinatorial metals are also envisaged as suitable materials. The inventors have recognized that use of bulk or monolithic deposition of these exemplary conductive materials may result in undesirable properties in the resulting structure. These undesirable properties can include (for example) line edge roughness (LER), which is a measure of the variation along one single edge, and line width roughness (LWR), which is the variation between two edges, and spacing width roughness (SpWR).

Accordingly, embodiments of the present invention will now be described with reference to the drawings, wherein like reference numerals are used to refer to like elements throughout. It should be understood that the description of these aspects are merely illustrative and that they should not be taken in a limiting sense. In the following description, for purposes of explanation, numerous specific details are set forth in order to provide a thorough understanding of the present invention. It will be evident to one skilled in the art, however, that the present invention may be practiced without these specific details.

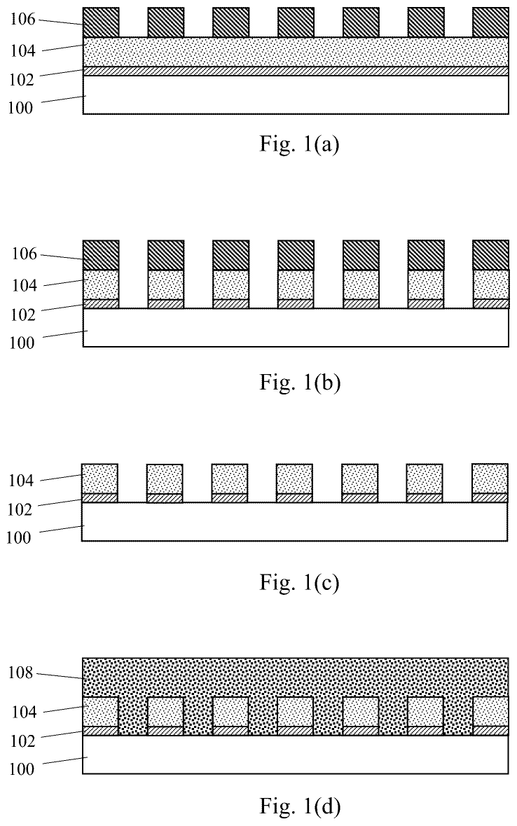

Referring initially to FIG. 1(a) though 1(e), there is shown a series of cross-sectional views illustrating a conventional process of forming metal lines for a semiconductor device. As shown in FIG. 1(a), a semiconductor device substrate 100 has a metal adhesion layer 102 formed thereon, followed by a blanket metal layer 104 (e.g., Ru formed by chemical vapor deposition (CVD)) and a patterned hardmask layer 106 formed over the metal layer. The metal layer 104 may be formed at an exemplary thickness of about 60 nm in a single deposition step. FIG. 1(b) illustrates transfer of the pattern defined by the hardmask layer 106 into the metal layer 104 and adhesion layer 102 such as by reactive ion etching (RIE) for example, after which the hardmask layer 106 is removed as shown in FIG. 1(c). Then, as shown in FIG. 1(d), a dielectric layer 108 (e.g., SiO2, SiN, low-K dielectric material, etc.) is formed over the patterned metal layer 104. This is followed by a planarizing of the dielectric layer 108 as shown in FIG. 1(e) and continuing with further processing such as by adding one or more additional connecting metal layers 110 to be further patterned (not illustrated). As will be recognized by one skilled in the art, this type of metal line formation is known as a subtractive process, as opposed to a damascene or dual damascene process. Damascene processing is an additive process in which the dielectric layer is first formed and patterned, and thereafter the metal material is formed into the openings in the dielectric layer and then planarized.

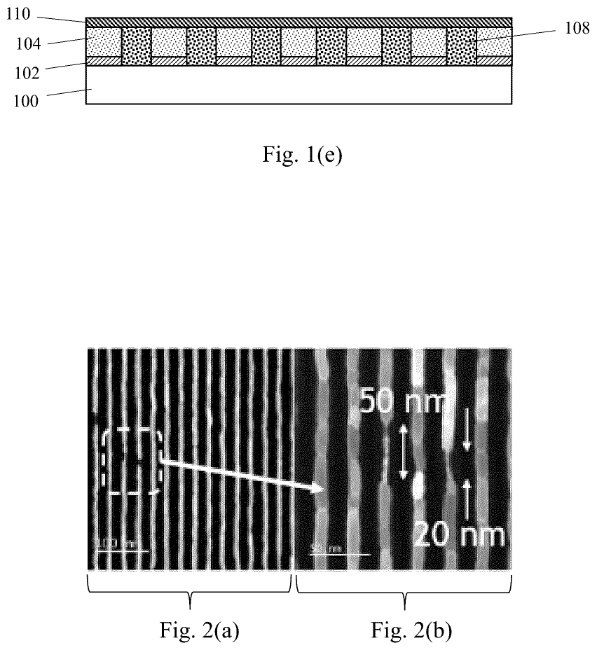

In such a subtractive process flow as described above, where the patterning and subsequent metal etch results in relatively high aspect ratio features and a narrow line width (e.g., about 20 nm or less) certain defects may be result with respect to the resulting structure. These defects may include, for example, incomplete etching, a “belly” formation at middle portions of the metal line height, and other non-desirable shapes. Moreover, such defective shapes, which should ideally be rectangular in cross section and with regular spacing between adjacent lines, may result in line-to-line shorts and/or open circuits. By way of further illustration, FIG. 2(a) and 2(b) are images of patterned metal lines formed by the process of FIG. 1(a)-1(e), and particularly show examples of irregular line shapes.

The present disclosure has recognized that the use of an implantation process following a partial deposition of a conductive interconnect material (such as ruthenium for example) can relax stress built up within the layer as it is formed. That is, instead of a single metal deposition step completed to a desired final thickness, the conductive metal deposition can be carried out in “stages” where a portion (e.g., about half) of the desired final metal layer thickness is initially formed, followed by an ion implant into the surface of the incomplete metal layer, followed by another metal deposition step to obtain the desired final metal layer thickness. In one embodiment, this ion implant can be done once or, alternatively, multiple times after partial metal layer thicknesses are added. As a result of this at least one implantation step, stresses related to phenomena such as increased grain size growth and surface tension otherwise causing top line roundness and mid-line bulging can be alleviated. In turn, the resulting final metal line is more uniformly etched.

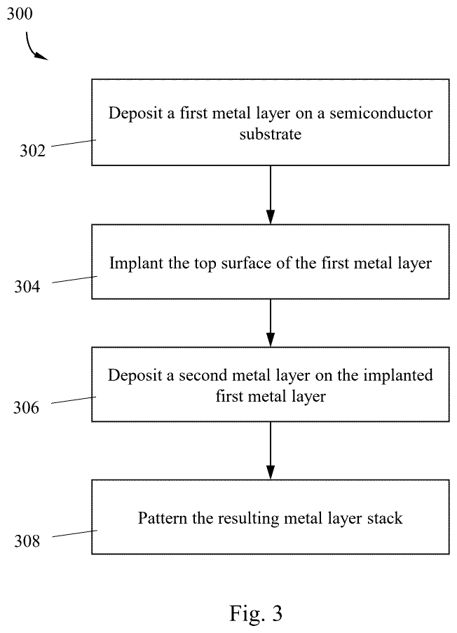

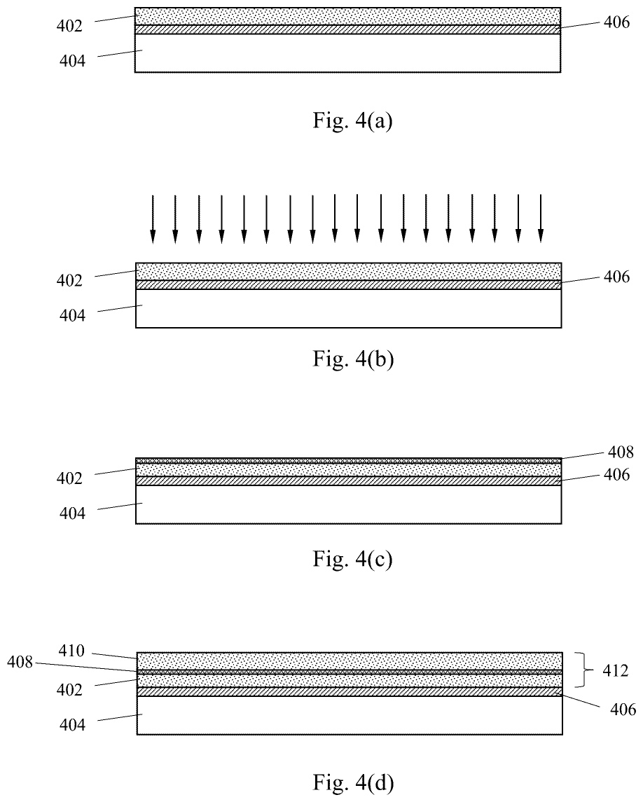

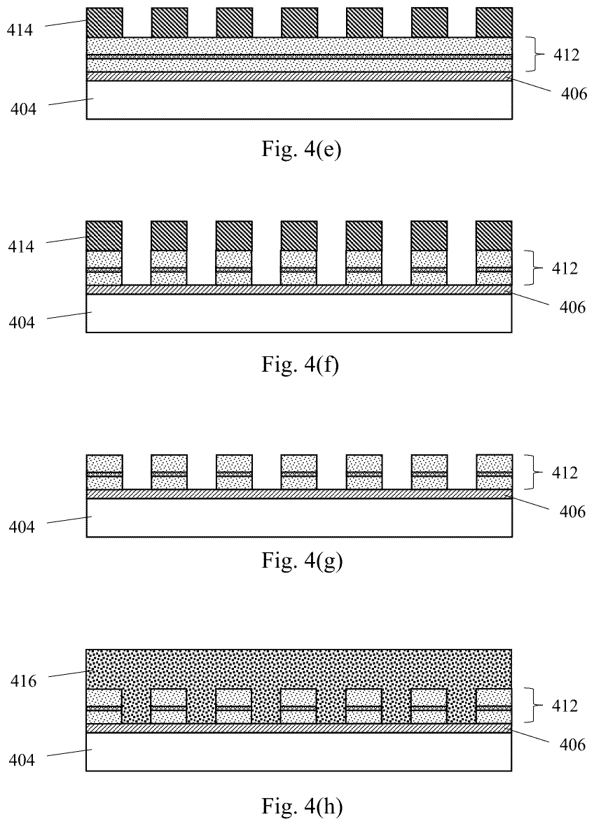

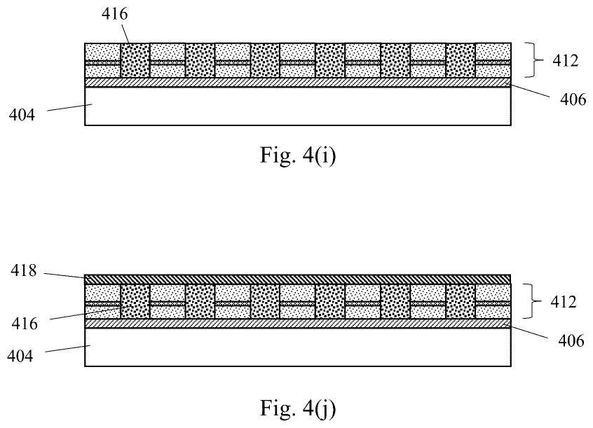

Referring simultaneously now to FIG. 3 and FIG. 4(a) through 4(j), a method 300 of forming an interconnect layer for a semiconductor device using selective ion implantation is illustrated. For purposes of illustration, it is assumed that semiconductor devices are formed on a semiconductor substrate, and the process has progressed to the BEOL stage of manufacturing. As described in block 302 of FIG. 3, and illustrated in FIG. 4(a), a first metal layer 402 is deposited on a semiconductor substrate 404, such as by chemical vapor deposition (CVD) of ruthenium for example. Other metal materials (e.g., molybdenum) may also be used. This process may also incorporate the formation of a metal adhesion layer 406 prior to deposition.

It should be noted that the thickness of the first metal layer 402 is less than the desired final layer thickness of the interconnect layer to be formed, such as about 50% or less than the desired final layer thickness for example. Following deposition of the first metal layer 402, a top surface of the first metal layer 402 is implanted as indicated in block 304 of FIG. 3 and illustrated by the arrows in FIG. 4(b). The ion beam may, for example, include an ion species such as titanium, xenon, argon, cobalt and tantalum. An exemplary ion energy range of the ion species may, for example, be between about 0.3 keV and about 10 keV. In an exemplary embodiment, the ions may be implanted to a total dose of about 1E15 to 5E15 atoms/cm². As a result of the implantation process, a modified deposition layer 408 is formed at a top portion of the first metal layer 402, as shown in FIG. 4(c).

Following the ion implant, the method 300 continues as indicated in block 306 of FIG. 3 and shown in FIG. 4(d) by performing a deposition of a second conductive layer 410 on top of the modified layer 408. The second deposition may, for example, be accomplished by such deposition processes as PVD, CVD or other similar methods. The second deposition may continue until a desired final thickness is attained for the resulting interconnect layer 412. In other embodiments (not shown) the resultant thickness may be less than the desired final thickness. In these non-limiting embodiments, the second layer, for example, may be further subject to ion bombardment and a third layer then deposited in order to attain the desired final thickness. Upon completion of the final desired thickness of the metal interconnect layer 412, the layer 412 may be patterned during further processing as known in the art as indicated in block 308 of FIG. 3.

As indicated above, it is believed that one or more ion implant process during the formation of the metal layer results in an etch process enhancement by relaxing the stress built up during metal film deposition. As a result of this implantation process, there is amelioration of the increase in grain size and surface tension, and furthermore metal residue left at the bottom of canyon can be removed by thin ion implantation insertion, which alleviates the stress. It is more efficient to irradiate the top surface with ions because the surface of thinner metals (e.g., Ru/Mo) will have a manageable stress to relax by low energy ion implantation. The LER, LWR and SpWR of the subsequently etched metal interconnect layer 412 are thereby substantially improved over the structure shown in FIG. 2(b).

In block 308 of FIG. 3, the resulting metal layer stack is patterned in accordance with further BEOL processing, and as illustrated in FIG. 4(e)-4(j). More specifically, FIG. 4(e) illustrates the formation and pattering of a hardmask layer 414 over the metal interconnect layer 412. The hardmask pattern is then transferred into the metal interconnect layer 412 such as by etching as shown in FIG. 4(f), after which the hardmask material is removed as shown in FIG. 4(g).

Because the illustrated embodiment is not a damascene process, a dielectric layer 416 is formed over the patterned metal interconnect layer 412 in FIG. 4(h), followed by planarization of the dielectric layer 416 in FIG. 4(i). From there, additional processing as known in the art may continue, such as forming additional connecting layers 418 in FIG. 4(j).

It will be appreciated by those of ordinary skill in the art that the above methods are not limited in application to the formation of interconnects on the wafer frontside. They may also, for example, be applied to the formation of BSPDN (backside power distribution networks) on the wafer backside. In further embodiments, they may also be applied to the formation of other structures such as vias or liners in other process steps on the wafer frontside.

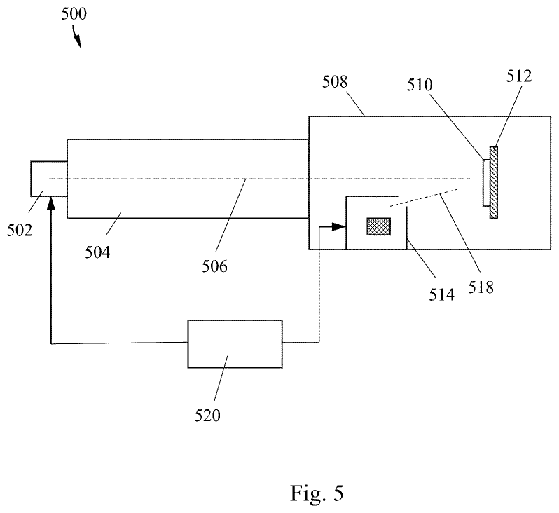

FIG. 5 depicts an exemplary semiconductor processing system 500 that may be configured to implement the exemplary methods described above, and which provide the further benefit of preventing the substrate from being exposed to ambient air between deposition and implantation steps. In the embodiment illustrated, the semiconductor processing system 500 may be considered as a combination ion implantation and deposition system that includes an ion source 502, operably coupled to a beamline module 504 of an ion implanter. This beamline module 504 may include, for example, components such as analyzing magnets, electrostatic deflectors, magnetic correctors, scanners or other similar devices (not specifically shown in FIG. 5) commonly associated with beamline modules and readily understood by one of ordinary skill in the art. An ion beam 506, originating from the ion source 502 and propagating through the beamline module 504, enters into a process chamber 508, and is implanted into a substrate 510. The substrate 510 may, for example, be mounted on a workpiece support platen 512. The workpiece support platen 512 may, for example, be an electrostatic chuck, or a mechanical clamp.

As further illustrated in FIG. 5, the process chamber 512 additionally includes a secondary chamber 514, within which is provided a deposition source 516. Material (e.g., conductive metal) desired to be deposited on the substrate 510 is emitted from the secondary chamber 516 in a directional jet 518 which coats the substrate 510 mounted on the workpiece support platen 512. As a result, implantation into the deposited layer can take place immediately thereafter, obviating the need to expose the wafer to an atmospheric environment by venting the substrate 510 and transferring it to another tool, thereby eliminating deleterious effects of exposure of the metals to oxygen. To this end, a system controller 520 may be configured to control both material deposition and ion implantation within the process chamber. It should be noted however, that the above described method embodiments could still be performed by using dedicated and separate deposition and ion implantation tools.

This disclosure provides many different embodiments, or examples, for implementing different features of the provided subject matter. Specific examples of components and arrangements are described below to simplify the present disclosure. These are, of course, merely examples and are not intended to be limiting. For example, the formation of a first layer on a second layer in the description above may include embodiments in which the first and second layers are formed in direct contact, and may also include embodiments in which additional features are disposed between the first and second layers, such that the first and second layers are not in direct contact. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “approximately”, “about” and “substantially” can indicate a value of a given quantity that varies within 5% of the value (e.g., ±1%, 2%, ±3%, ±4%, ±5% of the value). These values are merely examples and are not intended to be limiting. It is to be understood that the terms “approximately”, “about” and “substantially” can refer to a percentage of the values as interpreted by those skilled in relevant art(s) in light of the teachings herein.

1. A method for forming an interconnect layer for a semiconductor device, the method comprising:
depositing a first conductive layer on a semiconductor wafer, the first conductive layer having a thickness less than a desired final thickness of the interconnect layer;
implanting an implant species into a top surface of the first conductive layer, wherein the implant species is selected so as to mitigate a stress developed in the first layer; and
depositing one or more additional conductive layers upon the implanted first conductive layer up to the desired final thickness of the interconnect layer.

2. The method of claim 1, wherein the first conductive layer is one or more of Mo and Ru, and alloys thereof.

3. The method of claim 1, wherein the first conductive layer is graphene.

4. The method of claim 1, wherein the implant species is one or more of titanium, xenon, argon, cobalt and tantalum.

5. The method of claim 4, wherein the implant species is implanted at an energy from about 0.3 keV to about 10 keV.

6. The method of claim 5, wherein the implant species is implanted at a dose of about 1e15 atoms/cm² to about 5e15 atoms/cm².

7. The method of claim 6, wherein the desired final thickness of the interconnect layer is about 30 nanometers (nm) to about 90 nm.

8. The method of claim 1, wherein the one or more additional conductive layers comprise a same material as the first conductive layer.

9. The method of claim 1, wherein the depositing the first conductive layer, the implanting the implant species, and the depositing the one or more additional conductive layers are performed within a same processing chamber.

10. The method of claim 9, wherein the depositing the first conductive layer, the implanting the implant species, and the depositing the one or more additional conductive layers are performed without exposing the semiconductor wafer to an atmospheric environment.

11. A combination ion implantation and deposition system, the system comprising:
a process chamber;
an ion source configured to generate a desired ion species for implantation;
a beamline module configured to transport the desired ion species to the process chamber, wherein the process chamber further comprises a secondary chamber having a material deposition source therein; and
a controller configured to:
deposit, using the material deposition source, a first conductive layer on a semiconductor wafer disposed within the process chamber, the first conductive layer having a thickness less than a desired final thickness of an interconnect layer of a semiconductor device formed on the semiconductor wafer;
implant the desired implant species into a top surface of the first conductive layer, wherein the implant species is selected so as to mitigate a stress developed in the first layer; and
deposit, using the material deposition source, one or more additional conductive layers upon the implanted first conductive layer up to the desired final thickness of the interconnect layer.

12. The system of claim 11, wherein the first conductive layer is one or more of Mo and Ru, and alloys thereof.

13. The system of claim 11, wherein the first conductive layer is graphene.

14. The system of claim 11, wherein the implant species is one or more of titanium, xenon, argon, cobalt and tantalum.

15. The system of claim 14, wherein the implant species is implanted at an energy from about 0.3 keV to about 10 keV.

16. The system of claim 15, wherein the implant species is implanted at a dose of about 1e15 atoms/cm² to about 5e15 atoms/cm².

17. The system of claim 16, wherein the desired final thickness of the interconnect layer is about 30 nanometers (nm) to about 90 nm.

18. The system of claim 11, wherein the one or more additional conductive layers comprise a same material as the first conductive layer.
